(19) United States
(12) Patent Application Publication
(10) Pub. No.: US 2026/0122855 A1
(43) Pub. Date: Apr. 30, 2026

(54) APPARATUS FOR APPLYING THERMAL MATERIAL PATTERN TO ELECTRONIC DEVICE

(71) Applicant: Micron Technology, Inc., Boise, ID (US)

(72) Inventor: Boon Khian Foo, Singapore (SG)

(21) Appl. No.: 18/930,601

(22) Filed: Oct. 29, 2024

(51) Int. Cl. H05K 7/20

(52) U.S. Cl. CPC H05K 7/20418

(57) ABSTRACT

Various example embodiments of the present disclosure provide apparatuses (e.g., applicators) for applying patterns of thermal material (e.g., dispensable thermal interface material) to components of electronic devices, such as a PCB of a memory sub-system (e.g., memory module). In particular, various example embodiments involve disposing (e.g., printing or dispensing) a thermal material pattern onto a base material, using a pre-disposed (e.g., pre-printed or pre-disposed) thermal material pattern on a base material, or both. The pattern of thermal material can correspond to one or more components of an electronic device targeted to interface with at least one heat dissipation element (e.g., a heatsink, which can be part of an electronic device enclosure).

### TECHNICAL FIELD

Example embodiments of the disclosure relate generally to thermal material and, more specifically, to an apparatus for applying a pattern of dispensable thermal interface material to one or more components of an electronic device, such as a printed circuit board (PCB) of a memory sub-system.

### BACKGROUND

Thermal management is a critical aspect of electronic devices, such as memory sub-systems that include one or more memory devices (e.g., non-volatile memory devices and volatile memory devices) for storing data. For example, as the capacities and performance of solid-state drives (SSDs) and Compute Express Link (CXL) data storage modules continue to increase, so does the importance of effective heat dissipation to manage the thermal output from components and increased power consumption.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 through FIG. 3 illustrate example apparatuses for applying patterns of thermal material to components of electronic devices, in accordance with some embodiments of the present disclosure.

FIG. 4 is a flow diagram of an example method for manufacturing an apparatus for applying a pattern of thermal material to components of an electronic device, in accordance with some embodiments of the present disclosure.

FIG. 5 is a flow diagram of an example method for applying a pattern of thermal material to components of an electronic device, in accordance with some embodiments of the present disclosure.

FIG. 6 illustrates an example flow for applying a pattern of thermal material to components of an electronic device, in accordance with some embodiments of the present disclosure.

FIG. 7 through FIG. 11 illustrate an example device used to prepare (e.g., manufacture) an apparatus for applying a pattern of thermal material to components of an electronic device, in accordance with some embodiments of the present disclosure.

### DETAILED DESCRIPTION

A common approach to thermal management in electronic devices, such as memory sub-systems, is the use of dispensable thermal interface material (DTIM). DTIM is applied to various components within an electronic device (e.g., a memory sub-system) to facilitate heat transfer and dissipation. With respect to memory sub-systems, the number of components requiring DTIM application can vary significantly between product types. For example, some CXL data storage modules can require DTIM application on up to 78 components, compared to an average of 10 components in typical SSDs.

The conventional method of applying DTIM involves using a dispensing system to apply the material to individual components. However, this approach faces several challenges. For instance, the high viscosity of DTIM can lead to nozzle clogs in the dispensing system. This can necessitate frequent purging of the dispensing system, especially after short idle periods (e.g., periods of around 15 minutes). Accuracy and consistency can be another challenge, where the dispensing process can result in significant variations in the volume of DTIM applied (e.g., variations of up to ±30%). While the location accuracy can remain relatively high (e.g., at ±1mm), the volume inconsistency can impact thermal performance. Another challenge can be overcompensation, where to ensure adequate coverage and compensate for the volume variations, conventional methods of applying DTIM can involve applying 2 to 3 times the theoretically required volume of DTIM. With respect to material waste, the frequent purging of conventional methods of applying DTIM (to maintain nozzle functionality) can result in significant material wastage (e.g., up to 20% of DTIM may be lost). Lastly, some conventional methods of applying DTIM involve dispensing DTIM for individual components, which can lead to longer cycle times in the manufacturing process, especially for electronic devices with a high number of components that need DTIM application.

Aspects of the present disclosure are directed to apparatuses (e.g., applicators) for applying patterns of thermal material (hereafter also referred to as thermal material patterns) to components of (target) electronic devices, such as a PCB of a memory sub-system (e.g., memory module). In particular, various example embodiments involve disposing (e.g., printing or depositing) a thermal material pattern (e.g., DTIM pattern) onto a base material, using a pre-disposed (e.g., pre-printed or pre-disposed) thermal material pattern on a base material, or both. For some example embodiments, the pattern of thermal material corresponds to target one or more components (e.g., PCB components, such as circuit chips) of a target electronic device (e.g., a memory sub-system) intending to interface with a heat dissipation element (e.g., a heatsink, which can be part of an electronic device enclosure). For various example embodiments, the base material with the pre-disposed thermal material pattern serves as a thermal material pattern apparatus (e.g., applicator) used to dispose (e.g., apply, attach, or place) the thermal material pattern between the one or more components of the (target) electronic device (e.g., the memory sub-system) and a heat dissipation element (e.g., heatsink), which can be part of an enclosure of the electronic device that is disposed over the one or more components. Hereafter, a thermal material pattern apparatus (e.g., applicator) can refer to a base material with a pre-disposed thermal material pattern (e.g., DTIM pattern). Depending on the example embodiment, the base material with the pre-disposed thermal material pattern can be disposed on (e.g., attached to) a surface of the heat dissipation component/element prior to the heat dissipation element being combined with the electronic device or, alternatively, the base material with the pre-disposed thermal material pattern can be disposed on (e.g., attached to) a surface of the one or more components of the electronic device prior to the heat dissipation element being combined with the electronic device.

For some example embodiments, a base material comprises an adhesive layer and a reinforced backing layer (e.g., reinforced backing plate) attached to the adhesive layer, where the base material is attached to a separating sheet prior and where the reinforced backing layer has a set of cutouts that correspond to a set of components. According to various example embodiments, a thermal material pattern corresponding to the set of components is disposed (e.g., printed or dispensed) onto the base material such that each element of the thermal material pattern is disposed within a boundary of a corresponding cutout of the reinforced backing layer. During disposal (e.g., application, attachment, placement) of the thermal material pattern to the set of components, the thermal material pattern with the base material can be removed from the separating sheet (as one unit) and attached (e.g., applied or placed) to the set of components (e.g., attached to the PCB such that the cutouts of the reinforced backing layer align with the components) or attached (e.g., applied or placed) to a heat dissipation element that will be disposed (e.g., installed, attached, or placed) over the set of components.

Overall, various example embodiments provide a technical solution to technical problems, issues, and challenges of using traditional methods to apply thermal material (e.g., DTIM) to electronic devices (e.g., SSDs and CXL data storage modules). For example, use of some example embodiments can reduce or eliminate individual dispensing of thermal material (e.g., DTIM) on individual components. The thermal material pattern applicator of various example embodiments can facilitate quick and easy transfer (e.g., application) of a thermal material pattern over one or more components (e.g., PCB components) of an electronic device, thereby reducing cycle time during manufacturing. Additionally, the thermal material pattern applicator of various example embodiments can allow for easy application and conformity of thermal material to different surface heights of different components of an electronic device. Various example embodiments can facilitate improved accuracy and consistency in applying thermal material to components of an electronic device, thereby addressing thermal material volume variation issues and placement accuracy associated with traditional dispensing methods. Some example embodiments can reduce thermal material (e.g., DTIM) waste by eliminating the need for purging and excessive thermal material application. Furthermore, use of various example embodiments can provide a silicone oil barrier, where the reinforced backing layer can prevent (or assist in preventing) silicone oil from bleeding from thermal material (e.g., DTIM) onto an external surface of an enclosure, thereby addressing a cosmetic issues caused by different thermal materials. Accordingly, various example embodiments can enhance efficiency, reduce waste, and ensure more consistent application of thermal material on components of an electronic device during manufacturing processes.

As used herein, dispensable thermal interface material (DTIM) can comprise a thermal material in gel or paste form that can be dispensed onto a surface of a heat source or onto a surface of a heat dissipation element (e.g., heatsink) such that the thermal material is disposed between the surface of the heat source and the surface of the heat dissipation element after the heat source and the heat dissipation element are assembled together. The thermal material assists in thermal energy (e.g., heat) transfer from the heat source to the heat dissipation element. Examples of DTIM can include, without limitation, thermally conductive gels (e.g., THERM-A-GAP™ GEL 30 High Performance Fully Cured Dispensable Gel) or the like. Examples of heat dissipation elements can include, without limitation a heatsink or the like.

As used herein, a memory sub-system can be a data storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM). In general, a host system can utilize a memory sub-system that includes one or more components, such as memory devices that store data. The host system can send access requests to the memory sub-system, such as to store data at the memory sub-system and to read data from the memory sub-system. The host system can send access requests (e.g., write command, read command) to the memory sub-system, such as to store data on a memory device at the memory sub-system, read data from the memory device on the memory sub-system, or write/read constructs (e.g., such as submission and completion queues) with respect to a memory device on the memory sub-system.

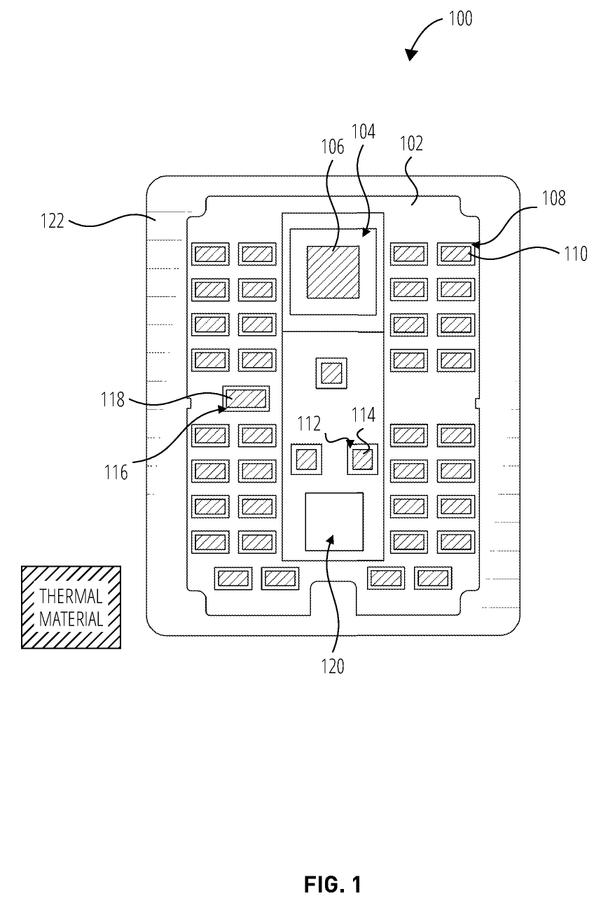

FIG. 1 through FIG. 3 illustrate example apparatuses for applying patterns of thermal material to components of electronic devices, in accordance with some embodiments of the present disclosure. In FIG. 1, an apparatus 100 comprises a separating sheet (now shown), a base medium disposed over the separating sheet (now shown), and a thermal material pattern (indicated by cross-hatching) disposed over the base medium. According to various example embodiments, the base medium comprises a reinforced backing layer 102, which comprising a plurality of cutouts (e.g., cutouts 104, 108, 112, 116) that expose multiple areas of an adhesive layer disposed underneath the reinforced backing layer 102. As shown, the thermal material is disposed (e.g., printed or deposited) on one or more individual area of the multiple areas of the adhesive layer exposed (through the reinforced backing layer 102) by the plurality cutouts. For various example embodiments, the thermal material comprises DTIM, such as a thermally conductive gel or the like. For various example embodiments, the reinforced backing layer 102 comprises a polyester film. For various example embodiments, the adhesive layer comprises an acrylic pressure-sensitive adhesive (PSA) layer. Additionally, for various example embodiments, the adhesive layer comprises a thermoplastic polymer layer (for added rigidity to the base medium), such as polyethylene terephthalate (PET). Alternatively, or additionally, the adhesive layer comprises a thermal conductive foil, such as a copper or aluminum conductive tape, or synthetic graphite sheet. Such an adhesive layer can can act as heat spreader and can be useful for high-temperature applications or environments. According to various example embodiments, an outer boundary of the base medium contours to different surface heights on a target surface to which the base medium will eventually be attached (e.g., affixed).

A layer of thermal material (e.g., represented by layers of thermal material 106, 110, 114, 118) in each of those one or more areas; each of those one or more areas can correspond to a component of an electronic device (e.g., memory sub-system) that (e.g., as a heat source) is to interface with a heat dissipation element using thermal material. For example, the layer of thermal material 106 (disposed on an area of the adhesive layer exposed by the cutout 104) can correspond to an Application-Specific Integrated Circuit (ASIC) of a PCB of the electronic device, the layer of thermal material 110 (disposed on an area of the adhesive layer exposed by the cutout 108) can correspond to a dynamic random access memory (DRAM) chip of the PCB, the layer of thermal material 114 (disposed on an area of the adhesive layer exposed by the cutout 112) can correspond to a voltage regulator (VR) of the PCB, and the layer of thermal material 118 (disposed on an area of the adhesive layer exposed by the cutout 116) can correspond to a Not-Or (NOR)-based memory chip of the PCB. For some example embodiments, a stencil is used to dispose a layer of thermal material to each of the one or more exposed areas of the adhesive layer. According to some example embodiments, when the base medium with the thermal material pattern is removed from the separating sheet, a border of reinforced backing layer 122 (that is not used in the application of the thermal material pattern to components of the electronic device) remains on the separating sheet. For some example embodiments, the separating sheet comprises a siliconized polyethylene (PE)-coated surface, which can enable the base medium (with thermal material pattern) to be easily removed (e.g., peeled) from the separating sheet.

For various example embodiments, the apparatus 100 represents an apparatus for applying (e.g., affixing) the thermal material pattern to an enclosure of the electronic device, where the enclosure comprises one or more heat dissipation elements and where the enclosure is configured to be disposed (e.g., installed) over components of the electronic device, such as PCB components (e.g., at least one packaged integrated circuit, such as chip) on the one side of a PCB of the electronic device.

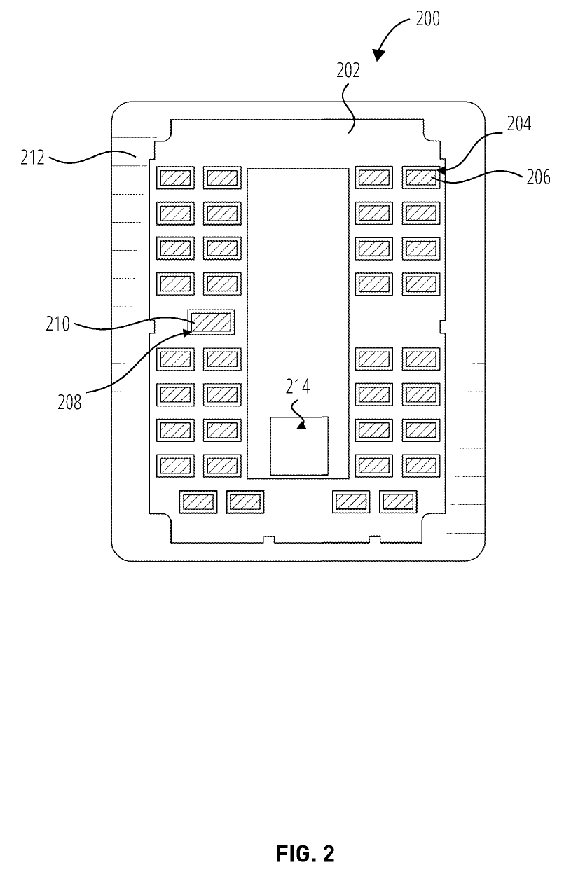

Referring now to FIG. 2, FIG. 2 illustrates an apparatus 200 for applying (e.g., affixing) the thermal material pattern to another enclosure of the electronic device, where the enclosure comprises one or more heat dissipation elements and where the enclosure is configured to be disposed (e.g., installed) over components of the electronic device, such as PCB components on the side of the PCB of the electronic device. The apparatus 200 can be similar to the apparatus 100 described and illustrated by FIG. 1. As shown, the apparatus 200 comprises a reinforced backing layer 202 that comprises multiple cutouts (e.g., 204, 208, 210, 214), layers of thermal material deposited on exposed areas of an adhesive layer (e.g., 206, 210), and a border of reinforced backing layer 212.

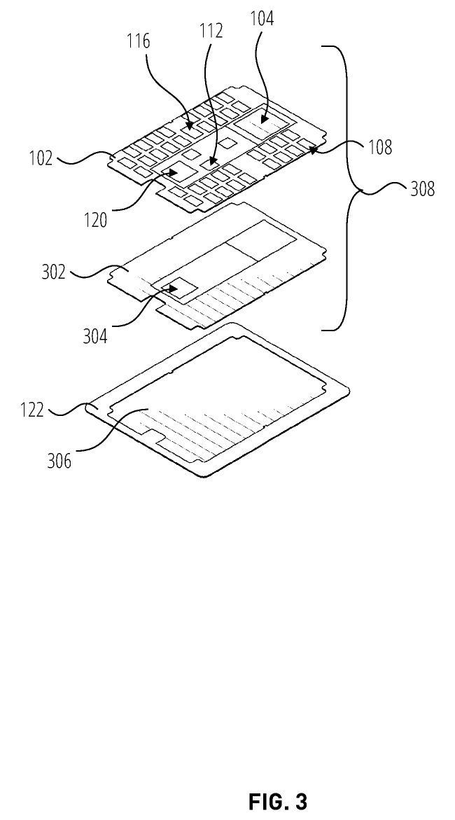

Referring now to FIG. 3, FIG. 3 illustrates an example construction of a base medium 308 of the apparatus 100. As shown, an adhesive layer 302 of the base medium is disposed between the reinforced backing layer 102 and a separating sheet 306 of the apparatus 100. As shown, the adhesive layer 302 can comprise one or more cutouts (e.g., 304), which can enable the base medium 308 to avoid certain elements on an intended surface (e.g., of an enclosure of the electronic device) when the base medium 308 is affixed to the surface (thereby enabling the base medium 308 to fit on the surface).

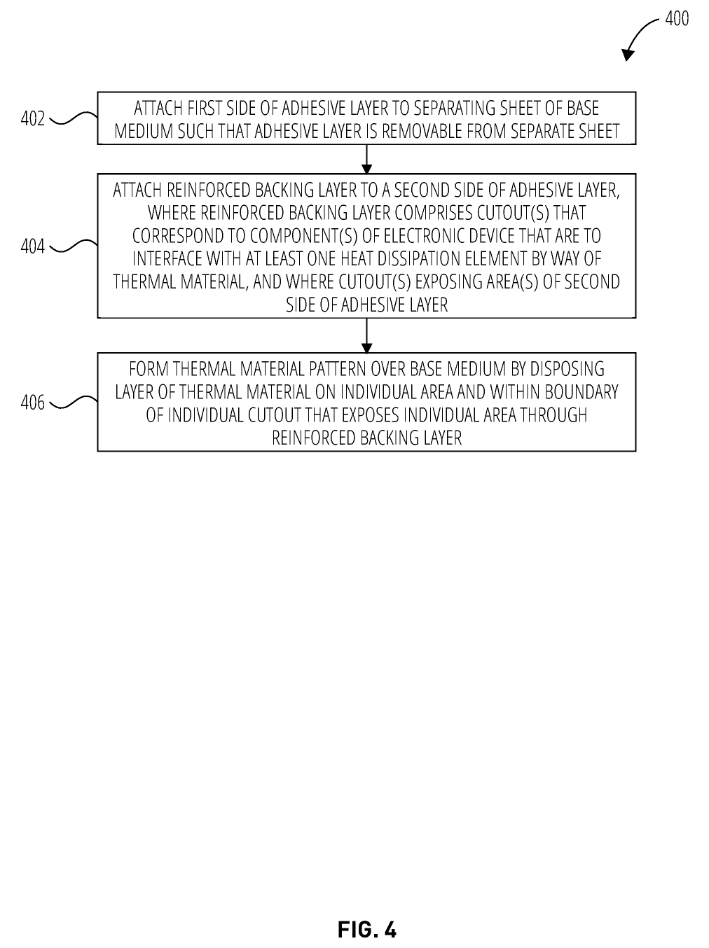

FIG. 4 is a flow diagram of an example method 400 for manufacturing an apparatus for applying a pattern of thermal material to components of an electronic device, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various example embodiments. Thus, not all processes are used in every example embodiment. Other process flows are possible.

Referring now to method 400, operations 402 and operation 404 will form a base medium (e.g., 308) disposed over a separating sheet (e.g., 306). According to various example embodiments, the base medium can serve as a medium to carry and apply a thermal material pattern with respect to an electronic device, such as a memory sub-system. Depending on the example embodiment, the separating sheet can have a siliconized PE coating.

At operation 402, a first side of an adhesive layer (e.g., 302) is attached (e.g., affixed) to a separating sheet (e.g., 306) such that the adhesive layer is removable from the separate sheet. Depending on the example embodiment, the adhesive layer can comprise an acrylic pressure-sensitive adhesive (PSA) layer, a thermoplastic polymer layer (e.g., polyethylene terephthalate (PET) layer), or both. For various example embodiments, the adhesive layer comprises a double-sided adhesive layer. For instance, the adhesive layer can comprise a PET layer (e.g., 0.025mm or 25um thick) sandwiched between two PSA layers. In this way, the PSA layers provide adhesion on both sides of the adhesive layer, while the PET layer provides some rigidity to the adhesive layer. For some example embodiments, the adhesive layer is rigid (e.g., strong) enough to hold the thermal material (e.g., DTIM) without breakage and the reinforced backing layer permits the pre-printed thermal material pattern (e.g., DTIM pattern) to be transferred (e.g., to an enclosure or over components of the electronic device) for application.

During operation 404, a reinforced backing layer (e.g., 102) is attached (e.g., affixed) to a second side of the adhesive layer (e.g., 302), where the second side is opposite the first side of the adhesive layer. For various example embodiments, the reinforced backing layer (e.g., reinforced backing plate) comprises a set of cutouts that correspond to a set of components of the electronic device that are to interface with at least one heat dissipation element (e.g., that is part of an enclosure for the electronic device) by way of the thermal material. For example, each component can have a top surface that can interface with at least one heat dissipation element by way of the thermal material. During operation (e.g., use) of the electronic device, a given component can be a heat source and the thermal material can assist or facilitate the transfer of thermal energy (e.g., heat) from the given component to a heat dissipation element, such as a heatsink, thereby permitting the given component to cool. For some example embodiments, the set of cutouts (e.g., 104, 108, 112, 116, 120) of the reinforced backing layer exposes a set of areas of the second side of the adhesive layer that underlies the reinforced backing layer. For some example embodiments, the reinforced backing layer comprises a polyester film, such as Melinex® 339 film, which is an opaque white polyester film. The reinforced backing layer can provide the base medium with rigidity, which can render the base medium easier to remove from the separating sheet and attached (e.g., to an enclosure of the electronic device) to facilitate application (e.g., transfer) of a thermal material pattern to one or more components of the electronic device.

At operation 406, a thermal material pattern (e.g., as shown in FIG. 1) is formed over the base medium by disposing a layer of thermal material (e.g., 106, 110, 114, 118) on at least one individual area of the set of areas and within a boundary of an individual cutout that exposes the at least one individual area through the reinforced backing layer. For example, a layer of thermal material can be disposed on each individual area of the set of areas of the second side of the adhesive layer exposed by the set of cutouts. The individual layers of thermal material in combination form the thermal material pattern over the base medium. For various example embodiments, disposing a layer of thermal material on an individual area (e.g., each individual area) of the set of areas comprises using a screen printing process with a stencil. For some example embodiments, the stencil comprises a pattern of cutouts configured to cause the formation of the thermal material pattern during the screen printing process. During the screen printing process, the thermal material can be pushed through the stencil by way of a squeegee mechanism (which can be an automatic or manual process) that pulls the thermal material across the top of the stencil and causes the thermal material to push through the pattern of cutouts of the stencil and onto the base medium positioned below the stencil. The screen printing process can cause a layer of the thermal material to be disposed in one or more individual areas of the set of areas (of the second side of the adhesive layer of the base medium) while removing additional thermal material above the stencil, thereby limiting the height/thickness of each layer, resulting in the individual layers of thermal material having consistent thickness across the base medium, and limiting thermal material waste. The stencil can comprise a nano-coated stencil (e.g., to reduce or prevent the thermal material sticking to the stencil), and the stencil can be laser cut. Depending on the example embodiment, the stencil can have a thickness of 0.5mm to 2mm.

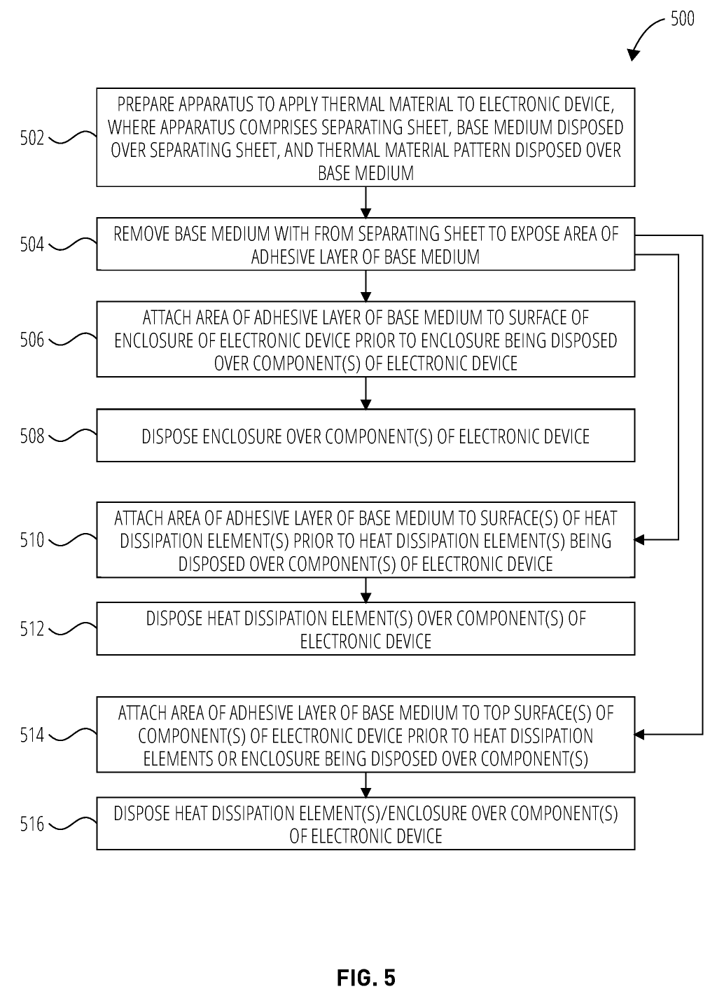

FIG. 5 is a flow diagram of an example method 500 for applying a pattern of thermal material to components of an electronic device, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various example embodiments. Thus, not all processes are used in every example embodiment. Other process flows are possible.

Referring now to method 500, at operation 502, an apparatus (e.g., 100) for applying a pattern of thermal material to a set of components of an electronic device is prepared. Operation 502 can comprise manufacturing the apparatus (e.g., according to method 400 of FIG. 4), or receiving the apparatus from a third-party that provides the apparatus (e.g., manufactures the apparatus according to method 400 of FIG. 4). According to various example embodiments, the apparatus comprises a separating sheet (e.g., 306), a base medium disposed over the separating sheet, and a thermal material pattern disposed over the base medium. For various example embodiments, the base medium comprises an adhesive layer comprising a first side and a second side, where the first side of the adhesive layer being removably attached to the separating sheet. For some example embodiments, the base medium comprises a reinforced backing layer attached to the second side of the adhesive layer, where the reinforced backing layer comprises a set of cutouts that correspond to the set of components of the electronic device that are to interface with at least one heat dissipation element by way of the thermal material. For various example embodiments, the set of cutouts expose a set of areas of the second side of the adhesive layer. Additionally, the thermal material pattern comprises a layer of thermal material disposed on an individual area (e.g., each individual area) of the set of areas and within a boundary of an individual cutout that exposes the individual area (e.g., within the boundary of respective cutouts) through the reinforced backing layer.

At operation 504, the base medium with the thermal material pattern (e.g., 610) is removed from the separating sheet to expose an area of the first side of the adhesive layer of the base medium. Thereafter, depending on the example embodiment, method 500 proceeds to operation 506, operation 510, or operation 514.

During operation 506, the area of the first side of the adhesive layer of the base medium is attached to a surface of an enclosure (e.g., 614) of the electronic device prior to the enclosure being disposed over the set of components (e.g., of the memory sub-system), where the area of the first side is attached to the surface when the surface of the enclosure is disposed over the set of components, the thermal material pattern and the set of cutouts of the reinforced backing layer align with corresponding components of the set of components. In particular, the surface of the enclosure can be the component-facing surface of the enclosure. Thereafter, at operation 508, the enclosure is disposed (e.g., installed) over the set of components of the electronic device.

At operation 510, the area of the first side of the adhesive layer of the base medium is attached to one or more surfaces of a set of heat dissipation elements prior to the set of heat dissipation elements being disposed over the set of components (e.g., of the memory sub-system), where the area of the first side is attached to the one or more surfaces such that when the one or more surfaces is disposed over the set of components, the thermal material pattern and the set of cutouts of the reinforced backing layer align with corresponding components of the set of components. During operation 512, the set of heat dissipation elements is disposed (e.g., installed) over the set of components of the electronic device.

For operation 514, the area of the first side of the adhesive layer of the base medium is attached to one or more top surfaces of the set of components prior to a set of heat dissipation elements or an enclosure (of the electronic device) being disposed over the set of components (e.g., of the memory sub-system), where the area of the first side is attached to the one or more top surfaces such that the thermal material pattern and the set of cutouts of the reinforced backing layer align with corresponding components of the set of components. At operation 516, the set of heat dissipation elements/enclosure is disposed (e.g., installed) over the set of components of the electronic device.

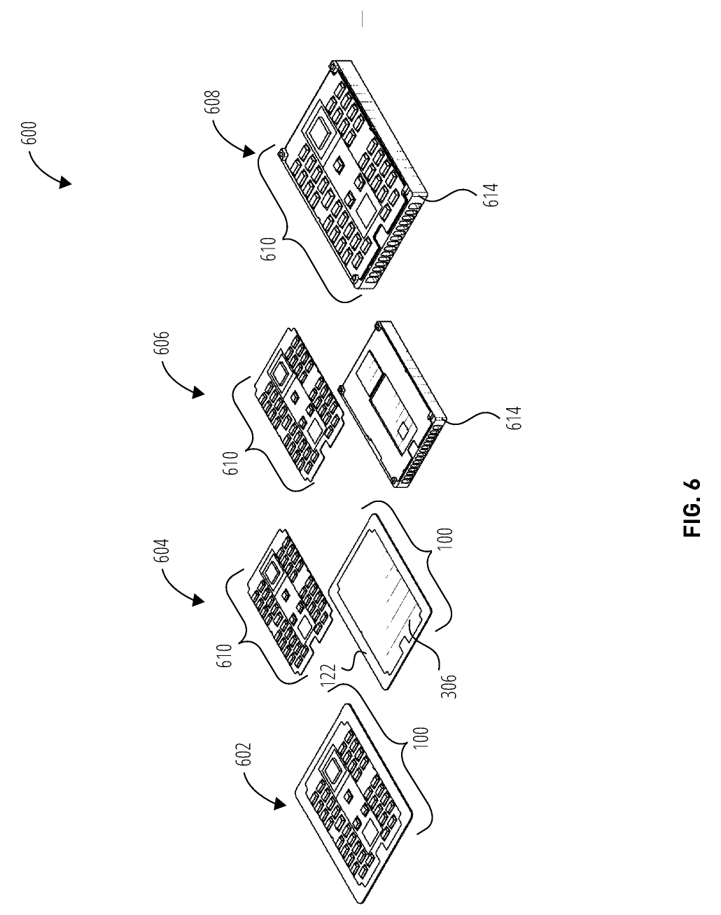

An example of using method 500 is described and illustrated with respect to FIG. 6.

FIG. 6 illustrates an example flow 600 of applying a pattern of thermal material to components of an electronic device, in accordance with some embodiments of the present disclosure. At stage 602, the apparatus 100 is received, where the apparatus 100 is configured to apply a thermal material pattern to an enclosure 614 of an electronic device, where the enclosure 614 comprises one or more heat dissipation elements. Then, at stage 604, the base medium with thermal material pattern 610 is removed from the separating sheet 306 (leaving behind the border of reinforced backing layer 122 on the separating sheet 306). During stage 606, the base medium with thermal material pattern 610 is positioned to be attached (e.g., affixed) on the enclosure 614. Then, at stage 608, the base medium with thermal material pattern 610 is attached to the 614. Thereafter, the resulting enclosure 614 (attached with the base medium with thermal material pattern 610) can be disposed (e.g., installed) over components of the electronic device.

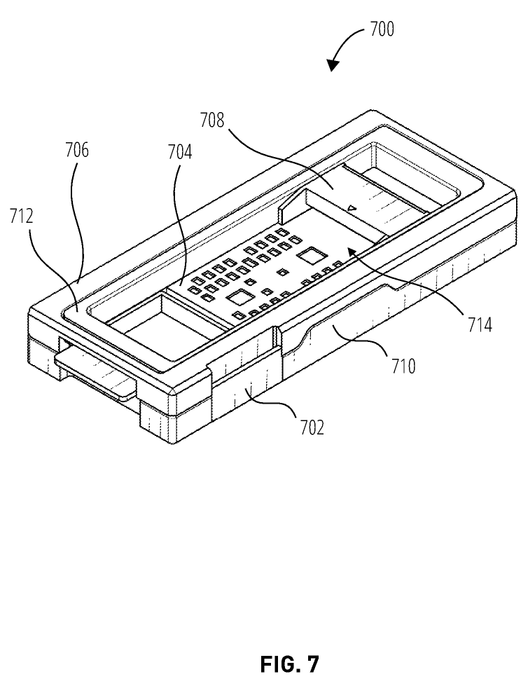

FIG. 7 through FIG. 11 illustrate an example device used to prepare (e.g., manufacture) an apparatus for applying a pattern of thermal material to components of an electronic device, in accordance with some embodiments of the present disclosure. In particular, FIG. 7 through FIG. 11 illustrate a thermal material disposition apparatus 700 used to disposition (e.g., print or deposit) a layer of thermal material on one or more areas of an adhesive layer of the apparatus (e.g., 100) exposed through a reinforced backing layer (e.g., 102), thereby forming a thermal material pattern on a base medium (e.g., 610).

Referring now to FIG. 7, as shown, the thermal material disposition apparatus 700 comprises a thermal material container 702, a stencil 704 (configured to disposing the thermal material pattern on a base medium), a frame cover 706, a squeegee mechanism 708 (e.g., to facilitate a screen printing process to dispose the thermal material pattern on the base medium), a base 710, and a frame 712. During use of the thermal material disposition apparatus 700, thermal material (e.g., DTIM) is deposited in area 714 in front of the squeegee mechanism 708. During a screen printing process to dispose the thermal material pattern onto a base medium, the squeegee mechanism 708 slides forward and pulls the thermal material across the top of the stencil 704, thereby causing the thermal material to push through a pattern of cutouts of the stencil 704 and onto a base medium positioned below the stencil 704 (e.g., positioned between the stencil 704 and the base 710). At the same time, the (excess) thermal material that does not push through the pattern of cutouts of the stencil 704 is pushed off the top of the stencil 704 and into the thermal material container 702, which can collect the thermal material. Depending on the example embodiment, the thermal material disposition apparatus 700 can be used part of a manual or automatic screen printing process for preparing (e.g., manufacturing) apparatuses for applying a pattern of thermal material to components of the electronic device.

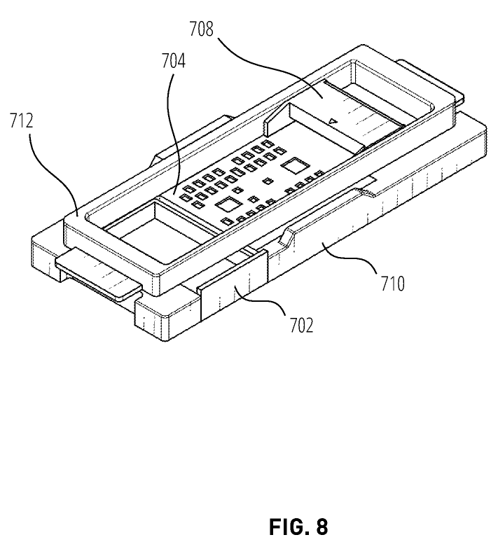

FIG. 8 illustrates a different view of the thermal material disposition apparatus 700 with the frame cover 706 removed (for illustrative purposes).

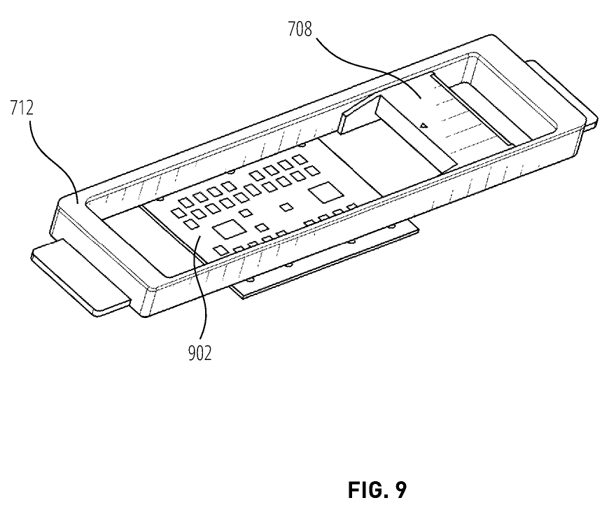

FIG. 9 illustrates another view of the thermal material disposition apparatus 700 (with components removed for illustrative purposes) and placement of a base medium 902 within the thermal material disposition apparatus 700. The base medium 902 is shown prior to thermal material pattern being disposed on the base medium 902.

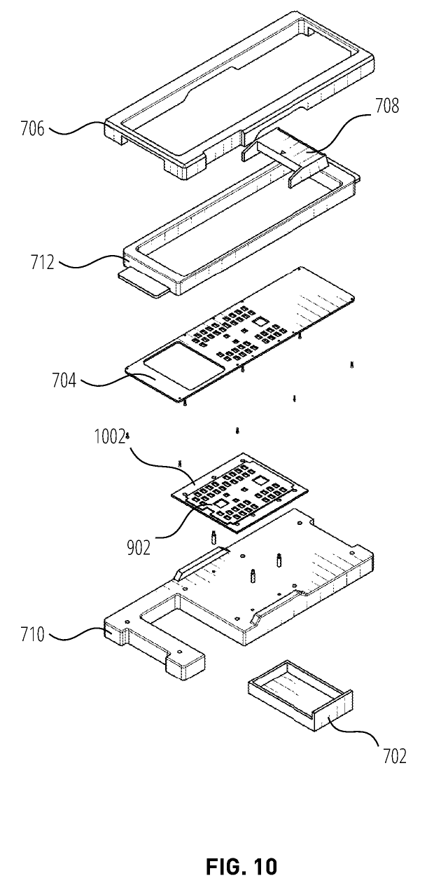

FIG. 10 illustrates an exploded view of the thermal material disposition apparatus 700 with the base medium 902 and support plate 1002 of the thermal material disposition apparatus 700.

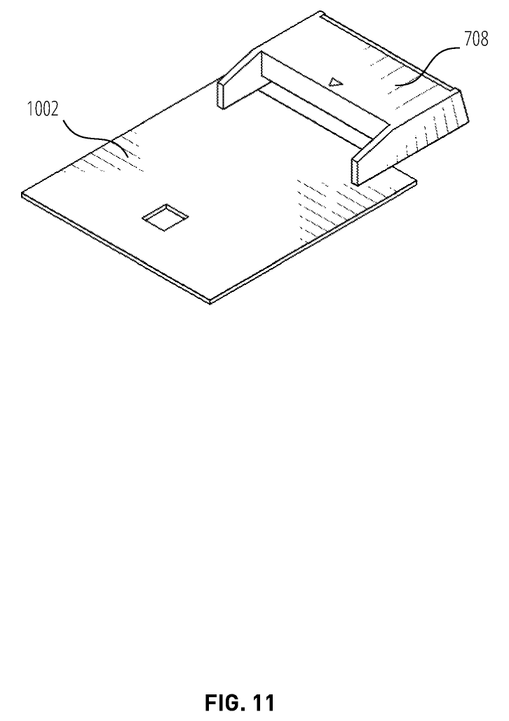

FIG. 11 illustrates another view of the thermal material disposition apparatus 700 with only the support plate 1002 and the squeegee mechanism 708.

Described implementations of the subject matter can include one or more features, alone or in combination as illustrated below by way of examples.

Example 1 is an apparatus for applying a thermal material to an electronic device, the apparatus comprising: a separating sheet; a base medium disposed over the separating sheet, the base medium comprising: an adhesive layer comprising a first side and a second side, the first side of the adhesive layer being removably attached to the separating sheet; and a reinforced backing layer attached to the second side of the adhesive layer, the reinforced backing layer comprising a set of cutouts that correspond to a set of components of the electronic device that are to interface with at least one heat dissipation element by way of the thermal material, the set of cutouts exposing a set of areas of the second side of the adhesive layer; and a thermal material pattern disposed over the base medium, the thermal material pattern comprising a layer of thermal material disposed on at least one individual area of the set of areas and within a boundary of an individual cutout that exposes the at least one individual area through the reinforced backing layer.

In Example 2, the subject matter of Example 1 includes, wherein the thermal material comprises dispensable thermal interface material (DTIM).

In Example 3, the subject matter of Examples 1–2 includes, wherein the reinforced backing layer comprises a polyester film.

In Example 4, the subject matter of Examples 1–3 includes, wherein the adhesive layer comprises an acrylic pressure-sensitive adhesive layer.

In Example 5, the subject matter of Examples 1–4 includes, wherein the adhesive layer comprises a thermoplastic polymer layer.

In Example 6, the subject matter of Example 5 includes, wherein the thermoplastic polymer layer comprises polyethylene terephthalate (PET).

In Example 7, the subject matter of Examples 1–6 includes, wherein the adhesive layer comprises a thermal conductive foil.

In Example 8, the subject matter of Examples 1–7 includes, wherein the separating sheet comprises a siliconized polyethylene (PE)-coated surface, and wherein the first side of the adhesive layer is disposed over the siliconized PE-coated surface.

In Example 9, the subject matter of Examples 1–8 includes, wherein the electronic device comprises a printed circuit board (PCB), and the set of components comprise PCB components.

In Example 10, the subject matter of Example 9 includes, wherein the set of PCB components comprises at least one packaged integrated circuit.

In Example 11, the subject matter of Examples 9–10 includes, wherein the PCB is part of a memory sub-system.

In Example 12, the subject matter of Examples 1–11 includes, wherein an enclosure for the electronic device comprises a set of heat dissipation elements, and wherein to apply the thermal material pattern to the set of components, prior to the enclosure being disposed over the set of components: the base medium with the thermal material pattern is removed from the separating sheet to expose an area of the first side of the adhesive layer; and the area of the first side of the adhesive layer is attached to a surface of the enclosure such that when the surface of the enclosure is subsequently disposed over the set of components, the thermal material pattern and the set of cutouts of the reinforced backing layer align with corresponding components of the set of components.

In Example 13, the subject matter of Example 12 includes, wherein an outer boundary of the base medium contours to different surface heights on a surface of the enclosure.

In Example 14, the subject matter of Examples 1–13 includes, wherein to apply the thermal material pattern to the set of components, prior to a set of heat dissipation elements being disposed over the set of components: the base medium with the thermal material pattern is removed from the separating sheet to expose an area of the first side of the adhesive layer; and the area of the first side of the adhesive layer is attached to one or more surfaces of the set of heat dissipation elements such that when the one or more surfaces of the set of heat dissipation elements is subsequently disposed over the set of components, the thermal material pattern and the set of cutouts of the reinforced backing layer align with corresponding components of the set of components.

In Example 15, the subject matter of Examples 1–14 includes, wherein to apply the thermal material pattern to the set of components, prior to a set of heat dissipation elements being disposed over the set of components: the base medium with the thermal material pattern is removed from the separating sheet to expose an area of the first side of the adhesive layer; and the area of the first side of the adhesive layer is attached to top surfaces of the set of components such that the thermal material pattern and the set of cutouts of the reinforced backing layer align with corresponding components of the set of components.

Example 16 is a method comprising: preparing an apparatus to apply a thermal material to an electronic device, the apparatus comprising: a separating sheet; a base medium disposed over the separating sheet, the base medium comprising: an adhesive layer comprising a first side and a second side, the first side of the adhesive layer being removably attached to the separating sheet; and a reinforced backing layer attached to the second side of the adhesive layer, the reinforced backing layer comprising a set of cutouts that correspond to a set of components of the electronic device that are to interface with at least one heat dissipation element by way of the thermal material, the set of cutouts exposing a set of areas of the second side of the adhesive layer; and a thermal material pattern disposed over the base medium, the thermal material pattern comprising a layer of thermal material disposed on an individual area of the set of areas and within a boundary of an individual cutout that exposes the individual area through the reinforced backing layer; removing the base medium with the thermal material pattern from the separating sheet to expose an area of the first side of the adhesive layer of the base medium; and attaching the area of the first side of the adhesive layer of the base medium to a surface of an enclosure of the electronic device prior to the enclosure being disposed over the set of components, the area of the first side being attached to the surface of the enclosure such that when the surface of the enclosure is disposed over the set of components, the thermal material pattern and the set of cutouts of the reinforced backing layer align with corresponding components of the set of components.

In Example 17, the subject matter of Example 16 includes, disposing the enclosure over the set of components of the electronic device.

In Example 18, the subject matter of Examples 16–17 includes, wherein the set of components comprises a printed circuit board (PCB) component.

Example 19 is a method comprising: forming a base medium by: attaching a first side of an adhesive layer to a separating sheet such that the adhesive layer is removable from the separating sheet; and attaching a reinforced backing layer to a second side of the adhesive layer, the reinforced backing layer comprising a set of cutouts that correspond to a set of components of an electronic device that are to interface with at least one heat dissipation element by way of thermal material, the set of cutouts exposing a set of areas of the second side of the adhesive layer; and forming a thermal material pattern over the base medium by disposing a layer of thermal material on an individual area of the set of areas and within a boundary of an individual cutout that exposes the individual area through the reinforced backing layer.

In Example 20, the subject matter of Example 19 includes, wherein the disposing of the layer of thermal material on the individual area and within the boundary of the individual cutout comprises: using a screen printing process with a stencil to dispose the layer of thermal material on the individual area, the stencil comprising a pattern of cutouts configured to cause formation of the thermal material pattern during the screen printing process.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. An apparatus for applying a thermal material to an electronic device, the apparatus comprising:
a separating sheet;
a base medium disposed over the separating sheet, the base medium comprising:
an adhesive layer comprising a first side and a second side, the first side of the adhesive layer being removably attached to the separating sheet; and
a reinforced backing layer attached to the second side of the adhesive layer, the reinforced backing layer comprising a set of cutouts that correspond to a set of components of the electronic device that are to interface with at least one heat dissipation element by way of the thermal material, the set of cutouts exposing a set of areas of the second side of the adhesive layer; and
a thermal material pattern disposed over the base medium, the thermal material pattern comprising a layer of thermal material disposed on at least one individual area of the set of areas and within a boundary of an individual cutout that exposes the at least one individual area through the reinforced backing layer.

2. The apparatus of claim 1, wherein the thermal material comprises dispensable thermal interface material (DTIM).

3. The apparatus of claim 1, wherein the reinforced backing layer comprises a polyester film.

4. The apparatus of claim 1, wherein the adhesive layer comprises an acrylic pressure-sensitive adhesive layer.

5. The apparatus of claim 1, wherein the adhesive layer comprises a thermoplastic polymer layer.

6. The apparatus of claim 5, wherein the thermoplastic polymer layer comprises polyethylene terephthalate (PET).

7. The apparatus of claim 1, wherein the adhesive layer comprises a thermal conductive foil.

8. The apparatus of claim 1, wherein the separating sheet comprises a siliconized polyethylene (PE)-coated surface, and wherein the first side of the adhesive layer is disposed over the siliconized PE-coated surface.

9. The apparatus of claim 1, wherein the electronic device comprises a printed circuit board (PCB), and the set of components comprise PCB components.

10. The apparatus of claim 9, wherein the set of PCB components comprises at least one packaged integrated circuit.

11. The apparatus of claim 9, wherein the PCB is part of a memory sub-system.

12. The apparatus of claim 1, wherein an enclosure for the electronic device comprises a set of heat dissipation elements, and wherein to apply the thermal material pattern to the set of components, prior to the enclosure being disposed over the set of components:
the base medium with the thermal material pattern is removed from the separating sheet to expose an area of the first side of the adhesive layer; and
the area of the first side of the adhesive layer is attached to a surface of the enclosure such that when the surface of the enclosure is subsequently disposed over the set of components, the thermal material pattern and the set of cutouts of the reinforced backing layer align with corresponding components of the set of components.

13. The apparatus of claim 12, wherein an outer boundary of the base medium contours to different surface heights on a surface of the enclosure.

14. The apparatus of claim 1, wherein to apply the thermal material pattern to the set of components, prior to a set of heat dissipation elements being disposed over the set of components:
the base medium with the thermal material pattern is removed from the separating sheet to expose an area of the first side of the adhesive layer; and
the area of the first side of the adhesive layer is attached to one or more surfaces of the set of heat dissipation elements such that when the one or more surfaces of the set of heat dissipation elements is subsequently disposed over the set of components, the thermal material pattern and the set of cutouts of the reinforced backing layer align with corresponding components of the set of components.

15. The apparatus of claim 1, wherein to apply the thermal material pattern to the set of components, prior to a set of heat dissipation elements being disposed over the set of components:
the base medium with the thermal material pattern is removed from the separating sheet to expose an area of the first side of the adhesive layer; and
the area of the first side of the adhesive layer is attached to top surfaces of the set of components such that the thermal material pattern and the set of cutouts of the reinforced backing layer align with corresponding components of the set of components.

16. A method comprising:
preparing an apparatus to apply a thermal material to an electronic device, the apparatus comprising:
a separating sheet;
a base medium disposed over the separating sheet, the base medium comprising:
an adhesive layer comprising a first side and a second side, the first side of the adhesive layer being removably attached to the separating sheet; and
a reinforced backing layer attached to the second side of the adhesive layer, the reinforced backing layer comprising a set of cutouts that correspond to a set of components of the electronic device that are to interface with at least one heat dissipation element by way of the thermal material, the set of cutouts exposing a set of areas of the second side of the adhesive layer; and
a thermal material pattern disposed over the base medium, the thermal material pattern comprising a layer of thermal material disposed on an individual area of the set of areas and within a boundary of an individual cutout that exposes the individual area through the reinforced backing layer;
removing the base medium with the thermal material pattern from the separating sheet to expose an area of the first side of the adhesive layer of the base medium; and
attaching the area of the first side of the adhesive layer of the base medium to a surface of an enclosure of the electronic device prior to the enclosure being disposed over the set of components, the area of the first side being attached to the surface of the enclosure such that when the surface of the enclosure is disposed over the set of components, the thermal material pattern and the set of cutouts of the reinforced backing layer align with corresponding components of the set of components.

17. The method of claim 16, comprising:
disposing the enclosure over the set of components of the electronic device.

18. The method of claim 16, wherein the set of components comprises a printed circuit board (PCB) component.

19. A method comprising:
forming a base medium by:
attaching a first side of an adhesive layer to a separating sheet such that the adhesive layer is removable from the separating sheet; and
attaching a reinforced backing layer to a second side of the adhesive layer, the reinforced backing layer comprising a set of cutouts that correspond to a set of components of an electronic device that are to interface with at least one heat dissipation element by way of thermal material, the set of cutouts exposing a set of areas of the second side of the adhesive layer; and
forming a thermal material pattern over the base medium by disposing a layer of thermal material on an individual area of the set of areas and within a boundary of an individual cutout that exposes the individual area through the reinforced backing layer.

20. The method of claim 19, wherein the disposing of the layer of thermal material on the individual area and within the boundary of the individual cutout comprises:
using a screen printing process with a stencil to dispose the layer of thermal material on the individual area, the stencil comprising a pattern of cutouts configured to cause formation of the thermal material pattern during the screen printing process.
